(19) United States
(12) Patent Application Publication
(10) Pub. No.: US 2023/0024555 A1
(43) Pub. Date: Jan. 26, 2023

(54) THERMAL CONDUCTION STRUCTURE, FORMING METHOD THEREOF, CHIP AND CHIP STACKING STRUCTURE

(71) Applicant: CHANGXIN MEMORY TECHNOLOGIES, INC., Hefei City, (CN)

(72) Inventor: Chih-Cheng LIU, Hefei (CN)

(21) Appl. No.: 17/515,783

(22) Filed: Nov. 1, 2021

Related U.S. Application Data
(63) Continuation of application No. PCT/CN2021/110135, filed on Aug. 2, 2021.

(30) Foreign Application Priority Data
Jul. 20, 2021 (CN) 202110821367.X

(51) Int. Cl. H01L 21/768; H01L 23/367; H01L 23/48; H01L 25/065

(52) U.S. Cl. CPC H01L 21/76898; H01L 23/367; H01L 23/481; H01L 25/0657; H01L 24/08

(57) ABSTRACT

A method for forming a thermal conduction structure includes: a substrate is provided, at least a dielectric layer being formed on the substrate; a Through Silicon Via (TSV) and at least one silicon blind hole are formed, where the at least one silicon blind hole is located on at least one side of the TSV, the TSV penetrates through the substrate and the dielectric layer, and each silicon blind hole does not penetrate through the substrate.

### CROSS-REFERENCE TO RELATED APPLICATIONS

This application is a continuation of International Application No. PCT/CN2021/110135, filed on Aug. 02, 2021, which claims priority to Chinese Patent Application No. 202110821367.X, filed on Jul. 20, 2021. The disclosures of International Application No. PCT/CN2021/110135 and Chinese Patent Application No. 202110821367.X are hereby incorporated by reference in their entireties.

### TECHNICAL FIELD

The embodiments of the disclosure relate to the technical field of semiconductors, and relate, but are not limited, to a thermal conduction structure, a method for forming a thermal conduction structure, a chip and a chip stacking structure.

### BACKGROUND

4X/8X Dynamic Random Access Memory (DRAM) chips are stacked through a traditional DRAM Through Silicon Via (TSV) technology, which is suitable for high-speed and broadband application.

In a related art, on one hand, because a plurality of layers of chips are stacked together through a TSV, high-density TSVs with small spacing and the stacked chips consume a lot of power, resulting in a sharp increase in power consumption density. The relatively high calorific value and the relatively poor heat dissipation make the working temperature of the chip to rise. However, only the first layer of chip is adjacent to a heat sink, so that it is very difficult to dissipate heat, resulting in too high heat density in the chip, and the reliability and the stability of the TSV are seriously disturbed. Therefore, thermal transmission becomes the key problem facing chip performance. On the other hand, an additional Thermal Transmission Line (TTL) will reduce the area efficiency and increase the process complexity.

### SUMMARY

The embodiments of the disclosure provide a thermal conduction structure, a method for forming a thermal conduction structure, a chip and a chip stacking structure.

According to a first aspect, the embodiments of the disclosure provide a method for forming a thermal conduction structure. The method may include the following operations. A substrate is provided, at least a dielectric layer being formed on the substrate. A TSV and at least one silicon blind hole are formed, where the at least one silicon blind hole is located on at least one side of the TSV, the TSV penetrates through the substrate and the dielectric layer, and each silicon blind hole does not penetrate through the substrate.

According to a second aspect, the embodiments of the disclosure provide a thermal conduction structure, which may include a substrate, a dielectric layer, a TSV and at least one silicon blind hole. The substrate is provided. The dielectric layer is formed on the substrate. The TSV penetrates through the substrate and the dielectric layer. The at least one silicon blind hole is located on at least one side of the TSV, and each silicon blind hole does not penetrate through the substrate.

According to a third aspect, the embodiments of the disclosure provide a chip stacking structure, which may include at least two chips, a pad and a bonding pad. Each of the at least two chips may include the above thermal conduction structure. The pad is located on the first surface of each chip, where the pad is connected with a TSV in the thermal conduction structure. The bonding pad is located on the second surface of the chip, where the bonding pad is connected with a metal layer connected with the TSV, and the second surface of the chip is a surface opposite to the first surface of the chip in the thickness of the chip. The pad on the first surface of the first chip of the at least two chips is electrically connected with the bonding pad on the second surface of the second chip of the at least two chips.

### BRIEF DESCRIPTION OF THE DRAWINGS

In the drawings (which are not necessarily drawn to scale), similar reference numbers may describe similar parts in different views. Similar reference numbers with different letter suffixes may represent different examples of similar parts. The drawings generally illustrate the various embodiments discussed herein by way of examples rather than limitation.

FIG. 1A is a flowchart schematic diagram of a forming method for a thermal conduction structure according to an embodiment of the disclosure.

FIG. 1B to FIG. 1E are top views of a positional relationship between a blind hole and a TSV according to an embodiment of the disclosure.

FIG. 2A to FIG. 4B is a flowchart of forming a thermal conduction structure according to an embodiment of the disclosure.

FIG. 5 is a schematic structural diagram of a chip according to an embodiment of the disclosure.

FIG. 6 is a schematic structural diagram of a circuit stacking structure according to an embodiment of the disclosure.

### DETAILED DESCRIPTION

In order to enable purposes, technical solutions and advantages of the embodiments of the disclosure to be more clearly, the specific technical solutions disclosed will be described in further detail below in combination with the drawings in the embodiments of the disclosure. The following embodiments are used to illustrate the disclosure, but are not used to limit the scope of the disclosure.

The embodiments of the disclosure provide a thermal conduction structure, a method for forming a thermal conduction structure, a chip and a chip stacking structure.

The embodiments of the disclosure are further described in detail through the drawings and specific embodiments below.

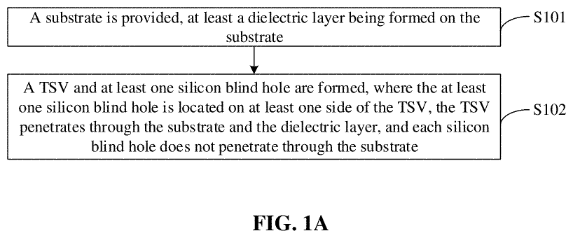

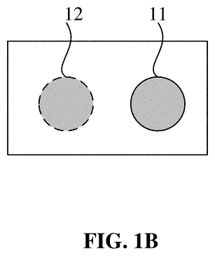

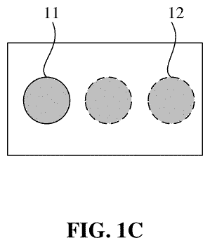

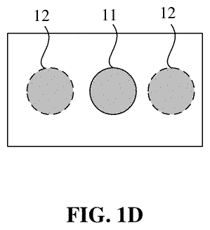

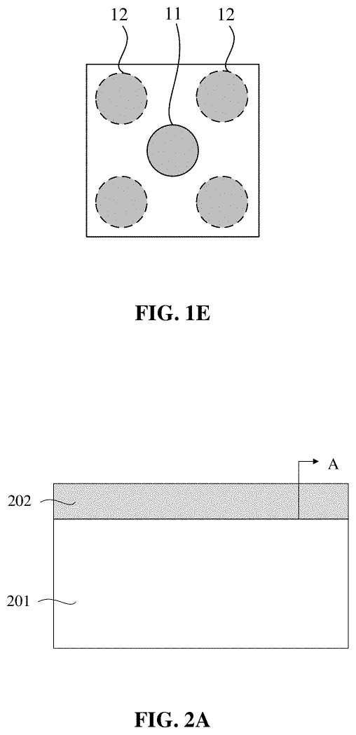

FIG. 1A is a flowchart schematic diagram of a method for forming a thermal conduction structure according to an embodiment of the disclosure. As shown in FIG. 1A, the method may include the following operations.

At S101, a substrate is provided, at least a dielectric layer being formed on the substrate.

In the embodiment of the disclosure, the substrate may be a silicon substrate, and the dielectric layer is formed on the surface of the substrate, and is configured to protect the silicon substrate. The material used for the dielectric layer may be silicon dioxide (SiO₂) or other insulating materials. The dielectric layer may be formed by the following methods: Chemical Vapor Deposition (CVD), Physical Vapor Deposition (PVD) or Atomic Layer Deposition (ALD).

At S102, a TSV and at least one silicon blind hole are formed, where the at least one silicon blind hole is located on at least one side of the TSV, the TSV penetrates through the substrate and the dielectric layer, and each silicon blind hole does not penetrate through the substrate.

The TSV is configured to perform signal transmission, and the silicon blind hole is configured to perform thermal transmission.

In some embodiments, a thickness of the substrate may be 40 μm to 70 μm; the purpose of setting the thickness of the substrate to be 40 μm to 70 μm is to make the total thickness of the subsequent substrate to meet packaging requirements. If the thickness of the initially provided substrate is too large, the substrate needs to be thinned The substrate may be thinned by mechanical grinding, Chemical Mechanical Polishing (CMP), wet etching, etc.

In some embodiments, a dielectric layer, an STI layer and a metal layer may also be sequentially formed on the substrate, and the TSV penetrates through the substrate, the dielectric layer and the STI layer and lands on the metal layer.

In some embodiments, an insulating layer, a barrier layer, a seed layer and a conductive layer sequentially formed are included in the TSV and each silicon blind hole, and a thickness of the insulating layer may be 2000 Å to 5000 Å.

In actual application, in the embodiments of the disclosure, there may be one, two, three or even more silicon blind holes. In order to make the thermal conduction effect better, there may be more than two silicon blind holes, which may be evenly distributed around the TSV.

In some embodiments, the at least one blind hole is located on at least one side of the TSV, which may include at least the following conditions.

The first condition is that, when there is one silicon blind hole, the silicon blind hole is arranged on any side of the TSV, such as any one of the front side, the rear side, the left side and the right side. As shown in FIG. 1B, the silicon blind hole 12 is arranged on the left side of the TSV 11.

The second condition is that, when there are two silicon blind holes, the two silicon blind holes may be arranged on any side of the TSV or on any two sides of the TSV respectively, such as left and right sides, front and rear sides, front side and left side, etc. When the two silicon blind holes are arranged on any side of the TSV, the two silicon blind holes and the TSV may be evenly or unevenly arranged in a straight line form. As shown in FIG. 1C, the two silicon blind holes 12 are arranged on the right side of the TSV 11 in a straight line form. As shown in FIG. 1D, the two silicon blind holes 12 are respectively arranged on the left and right sides of the TSV 11.

The third condition is that, when there are more than three silicon blind holes, more than three silicon blind holes are arranged around the TSV in a ring form, or on one or both sides of the TSV in a straight line form. As shown in FIG. 1E, the four silicon blind holes 12 are arranged around the TSV 11 in a ring form.

According to the method for forming a thermal conduction structure provided in the embodiments of the disclosure, since the heat conduction structure including the silicon blind hole is formed on at least one side of the TSV, the heat generated by the TSV may be dissipated to the outside of the substrate through the surrounding silicon blind hole, therefore, the reliability and the stability of the TSV are improved, and it is possible to solve the problem of reducing the area efficiency and increasing the process complexity caused by additional arrangement of the thermal transmission line.

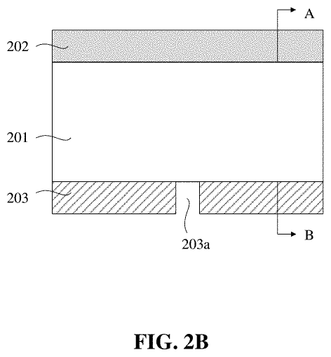

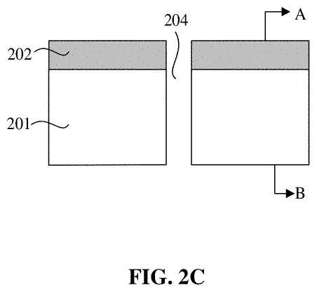

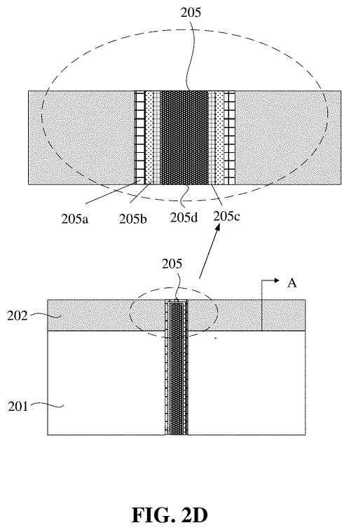

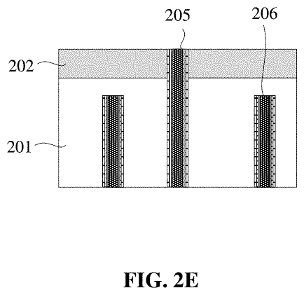

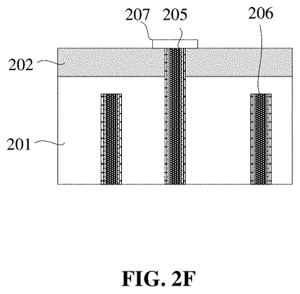

FIG. 2A to FIG. 4B are flowcharts of a method for forming a thermal conduction structure according to an embodiment of the disclosure. Afterwards, please referring to FIG. 2A to FIG. 4B, the method for forming a thermal conduction structure provided in the embodiments of the disclosure is further described in detail.

The embodiments of the disclosure further provide a method for forming a thermal conduction structure, which may include the following operations.

At S201, a substrate is provided, at least a dielectric layer being formed on a first surface of the substrate.

At S202, the substrate and the dielectric layer are etched from a second surface of the substrate to form a TSV penetrating through the substrate and the dielectric layer.

Herein, the second surface of the substrate is a surface opposite to the first surface of the substrate in a thickness direction of the substrate.

At S203, the substrate is etched from the second surface of the substrate to form at least one silicon blind hole which does not penetrate through the substrate.

In some embodiments, the etching process in S203 and the etching process in S202 may be implemented in a similar manner or in different manners. Various layers included in the silicon blind hole in S203 and various layers included in the TSV in S202 may be the same or different.

In the embodiment, the silicon blind hole(s) is/are formed around the TSV, and the silicon blind hole is filled with an insulating layer, a barrier layer, a seed layer and a conductive layer. In this way, the heat dissipation effect of the heat generated in the TSV may be improved by a simple process, so as to improve the reliability and the stability of the TSV.

In some embodiments, S202 may be achieved through the following steps.

At S2021a, a first photoresist layer is formed on a second surface of the substrate.

Herein, the first photoresist layer may be formed on the second surface of a silicon substrate by any proper deposition process. The material of the first photoresist layer may be a photoresist composed of Novolac resin, photosensitive naphthoquinone diazo compounds such as Diazo Naphtho Quinone (DNQ), and solvents and additives adjusting viscosity and other physicochemical properties; and it may also be a photoresist material of a Chemically Amplification Photoresist (CAMP) system or a chemically amplified photoresist.

At S2022a, the first photoresist layer is subjected to graphical treatment to form a first window, and the first window exposes a position corresponding to the TSV.

In some embodiments, the first photoresist layer may be subjected to graphical treatment through exposure, development and the like, so as to form the first window. In actual application, a mask and the substrate are aligned to expose the first photoresist layer to obtain the first window, and the finally formed TSV is located at the preset position.

At S2023a, the substrate and the dielectric layer are etched through the first window from the second surface of the substrate to form a through hole.

In some embodiments, the substrate and the dielectric layer may be etched by a dry etching process or a wet etching process to form the through hole. The dry etching process may be a plasma etching process, a reactive ion etching process or an ion milling process, the substrate and dielectric layer may also be etched by a Deep Reactive Ion Etching (DRIE) to obtain the through hole. A DRIE technology is that deposition of a polymer passivation layer and etching of monocrystalline silicon are combined together and performed circularly and alternately, so as to avoid the interaction between deposition and etching, ensure the stability and reliability of the passivation layer, and form a scallop structure with a steep side wall and a high aspect ratio. The most typical DRIE method is called a “Bosch” process. The specific process is as follows: the surface of silicon (Si) is etched with sulfur hexafluoride (SF₆), then a layer of polyfluorocarbon ((CF)ₙ) polymer passivation film is deposited on the side wall, then the passivation film is etched by introducing SF₆, and etching of the Si substrate is performed.

At S2024a, an insulating layer, a barrier layer, a seed layer and a conductive layer are sequentially formed in the through hole to obtain the TSV.

In some embodiments, the insulating layer is configured to isolate the conductivity between filler metal and Si and protect the substrate from damage; and the material of the insulating layer may be silicon oxide, silicon nitride and polymer. Different insulating layer materials need different deposition technologies. A silicon dioxide material may be deposited by adopting a thermal oxidation technology, a silicon dioxide material and a silicon nitride (Si₃N₄) material may be deposited by adopting a Plasma Enhanced Chemical Vapor Deposition (PECVD) technology, and a paraxylene material may be deposited by adopting a vacuum vapor deposition technology.

In some embodiments, the barrier layer is configured to prevent the diffusion of a conductive material subsequently filled in the TSV, the material of the barrier layer may be metal tantalum, tantalum nitride or titanium nitride, and the barrier layer may be formed by any proper deposition process.

In some embodiments, the seed layer is configured to provide a connecting effect for formation of the conductive layer in the TSV subsequently. The material of the seed layer may be any conductive material, such as tungsten (W), cobalt (Co), copper (Cu), aluminum (Al) or any combination thereof.

In some embodiments, the material of the conductive layer may be any conductive metal, such as W, Co, Cu, Al, polysilicon, doped silicon, silicide or any combination thereof, and the conductive material and a seed material may be the same or different. Generally speaking, the material of the conductive layer is Cu metal to form a Cu conductive layer, the seed layer may be deposited by PVD as the cathode of electroplating, and a layer of Cu may be deposited by Electro Chemical Plating (ECP) to form the conductive layer.

S2021a to S2024a are described with reference to FIG. 2A to FIG. 2D. As shown in FIG. 2A, the dielectric layer 202 is formed on a first surface of the substrate 201 (the surface A as shown in FIG. 2A). As shown in FIG. 2B, the first photoresist layer 203 is formed on the second surface of the substrate 201 (the surface B in FIG. 2B), and the first photoresist layer 203 is subjected to graphical treatment to form the first window 203a, which exposes the position corresponding to the TSV. As shown in FIG. 2C, the substrate 201 and the dielectric layer 202 are etched through the first window 203a to obtain the through hole 204. As shown in FIG. 2D, the insulating layer 205a, the barrier layer 205b, the seed layer 205c and the conductive layer 205d are sequentially formed on the inner wall of the through hole 204 to form the TSV 205 penetrating through the substrate.

Based on the process provided in FIG. 2A to FIG. 2D, the implementation process of S203 may be described with reference to FIG. 2E. The corresponding position of the silicon blind hole 206 is exposed on the second surface of the substrate, the substrate 201 is etched, and the silicon blind hole 206 without penetrating through the substrate 201 is obtained finally.

S2021a to S2024a are suitable for the following conditions.

The first condition is as follows: in S2021a, there are no other layers on the dielectric layer.

Other layers on the dielectric layer may be an STI layer and/or a metal layer. In practice, other layers are formed after the through hole is formed.

The second condition is as follows: in S2021a, other layers are formed on the dielectric layer, and other layers are formed before the through hole is formed.

In some embodiments, the through hole may penetrate through the dielectric layer and then penetrate through the substrate, that is, S202 may include S2021b to S2023b, where in S2021b, the first photoresist layer is formed on a first surface of the substrate; in S2022b, the first photoresist layer is subjected to graphical treatment to form the first window, the first window exposes the position corresponding to the TSV; and in S2023b, the dielectric layer and the substrate are etched through the first window from the first surface of the substrate to form the through hole.

S2021b to S2023b is suitable for the first condition, that is, in S2021b, there are no other layers on the dielectric layer. Other layers on the dielectric layer may be an STI layer and/or a metal layer. In practice, other layers are formed after the through hole is formed.

In some embodiments, after the through hole is formed through the first window in the first photoresist layer. The method for forming a thermal conduction structure may also include: the first photoresist layer is removed. In actual application, the first photoresist layer may be removed by the wet etching process or the dry etching process.

In some embodiments, when the insulating layer, the barrier layer and the seed layer are formed in the TSV, the insulating layer, the barrier layer and the seed layer are also formed on the second surface of the substrate at the same time. Therefore, before the silicon blind hole is formed, the second surface of the substrate needs to be subjected to CMP to remove the insulating layer, the barrier layer and the seed layer on the second surface of the substrate, and the second surface of the silicon substrate is exposed.

Based on FIG. 2E, the embodiments of the disclosure further provide a thermal conduction structure, which may include a substrate 201, a dielectric layer 202, a TSV 205 and at least one silicon blind hole 206.

The substrate 201 is provided.

The dielectric layer 202 is formed on the substrate 201.

The TSV 205 penetrates through the substrate 201 and the dielectric layer 202.

The at least one silicon blind hole 206 is located on at least one side of the TSV 205, and each silicon blind hole 206 does not penetrate through the substrate 201.

In some embodiments, as shown in FIG. 2F, the substrate 201 may also include a metal layer 207 formed on the dielectric layer 202, and the TSV 205 lands on the metal layer 207. The material of the metal layer may be Cu. Based on FIG. 2F, the structure may also include a metal layer 207 formed on the dielectric layer 202, and the TSV 205 lands on the metal layer 207.

The embodiments of the disclosure further provide a method for forming a thermal conduction structure, which may include the following operations.

At S301, a substrate is provided, where at least a dielectric layer is formed on the substrate, the substrate may also include a metal layer formed on the dielectric layer, and the TSV lands on the metal layer.

At S302, the substrate is etched from a second surface of the substrate to form at least two blind holes which do not penetrate through the substrate.

Herein, compared with the second surface of the substrate, the metal layer is close to the first surface of the substrate, the second surface of the substrate refers to a surface opposite to the first surface of the substrate in a thickness direction of the substrate.

At S303, one of the at least two blind holes is continuously etched to form the TSV.

At S304, the silicon blind hole is formed in each remaining blind hole of the at least two blind holes.

In some embodiments, S202 may be achieved through the following steps.

At S3021, a second photoresist layer is formed on a second surface of the substrate.

Herein, the second photoresist layer may be formed on the second surface of the silicon substrate by any proper deposition process, and the material of the second photoresist layer and the material of the first photoresist layer may be the same or different.

At S3022, the second photoresist layer is subjected to graphical treatment to form a second window and a third window.

Herein, the second window exposes the position corresponding to the TSV, and the third window exposes the position corresponding to the silicon blind hole.

In some embodiments, the second photoresist layer may be subjected to graphical treatment through exposure, development and the like, so as to form the second window and the third window.

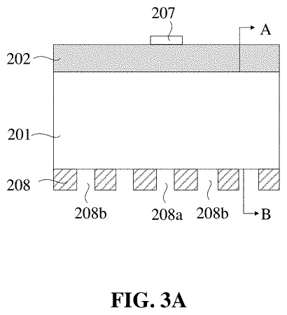

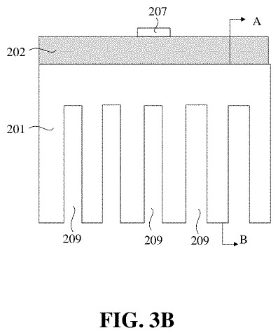

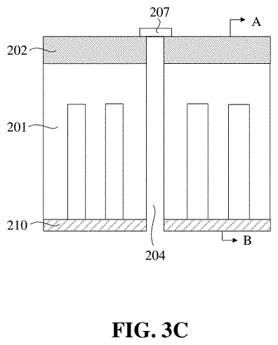

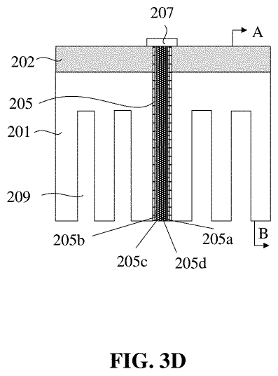

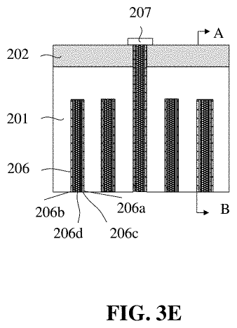

S3021 and S3022 are described with reference to FIG. 3A, the second photoresist layer 208 is formed on the second surface of the substrate 201 (the surface B in FIG. 3A), the second photoresist layer 208 is subjected to graphical treatment to form the second window 208a and the third window 208b, the second window 208a and the third window 208b expose the second surface of the substrate 201, the second window 208a exposes the position corresponding to the TSV, and the third window 208b exposes the position corresponding to the silicon blind hole.

At S3023, the substrate is etched through the second window and the third window to form at least two blind holes which do not penetrate through the substrate.

S3021 refers to FIG. 3B, the substrate 201 is etched through the second window 208a and the third window 208b to form at least two blind holes 209 which do not penetrate through the substrate 201, the blind hole has a first depth, and the first depth is less than the thickness of the substrate.

In some embodiments, S303 may include continuing to etch the blind hole located in a middle of the substrate among the at least two blind holes to form the TSV. Herein, the blind hole located in the middle of the substrate may be a blind hole located in the middle of the substrate among a plurality of blind holes arranged in a linear form, or a blind hole located in the center of the substrate among a plurality of blind holes arranged in a ring form.

In some embodiments, S303 may be achieved through the following steps.

At S3031, a protection layer is formed on each remaining blind hole.

The protection layer is configured to protect each remaining blind hole from etching. The material of the protective layer may be photoresist, and may also be silicon oxide, silicon oxynitride, silicon carbide and their combinations, and/or other proper materials. The protection layer may be formed by any proper deposition process.

At S3032, the substrate and the dielectric layer in the blind hole corresponding to the TSV are etched to form a through hole.

At S3033, an insulating layer, a barrier layer, a seed layer and a conductive layer are sequentially formed in the through hole to obtain the TSV.

At S3034, the protection layer is removed.

S3031 to S3034 are described with reference to FIG. 3C to FIG. 3D. As shown in FIG. 3C, the protection layer 210 is formed on each remaining blind hole 209. The substrate 201 and the dielectric layer 202 in the blind hole 209 are etched from the second surface of the substrate 201 to form the through hole 204. As shown in FIG. 3D, the insulating layer 205a, the barrier layer 205b, the seed layer 205c and the conductive layer 205d are sequentially formed in the through hole 204 to obtain the TSV 205. The protection layer 210 is removed.

In some embodiments, as shown in FIG. 3E, S304 may be realized by sequentially forming the insulating layer 206a, the barrier layer 206b, the seed layer 206c and the conductive layer 206d in each remaining blind hole 209 to obtain the silicon blind hole 206.

In some embodiments, various layers included in the silicon blind hole and various layers included in the TSV may be different or the same. In actual application, various layers included in the silicon blind hole and various layers included in the TSV are same. S3034 may be directly performed after S3032. Meanwhile, various layers of materials are deposited in the through hole and the remaining blind holes to form different layers, for example, the insulating layer, the barrier layer, the seed layer and the conductive layer are deposited to form the TSV and the silicon blind hole respectively. There is no need to deposit the insulating layer, the barrier layer, the seed layer and the conductive layer in the through hole and the remaining blind holes in two processes, so as to achieve the effect of simplifying the process.

In some embodiments, according to the method, the insulating layer, the barrier layer, the seed layer and the conductive layer sequentially formed are included in the TSV and each silicon blind hole, and a thickness of the insulating layer may be 2000 Å to 5000 Å.

In some embodiments, the insulating layers of the TSV and the silicon blind hole that are adjacent to each other are spaced apart by a distance of 1.5 μm, and/or the insulating layers of two adjacent silicon blind holes are spaced apart by a distance of 1.5 μm. By setting the above distance parameters, the thermal conduction efficiency may be improved, the reliability and stability of the TSV may be further improved, and the grounding noise may be reduced.

In some embodiments, a thickness of the insulating layer in the TSV is greater than a thickness of the insulating layer in the silicon blind hole.

The embodiments of the disclosure further provide a method for forming a thermal conduction structure, which may include the following operations.

At S401, a substrate is provided.

At S402, the STI layer, the dielectric layer and the metal layer are sequentially formed on the substrate.

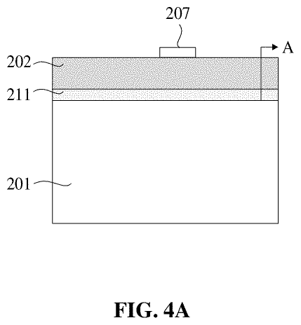

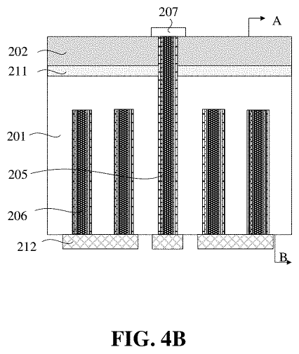

S401 and S402 are described with reference to FIG. 4A, the STI layer 211, the dielectric layer 202 and the metal layer 207 are sequentially formed on a first surface of the substrate 201.

At S403, a TSV and at least one silicon blind hole are formed, where the at least one silicon blind hole is located on at least one side of the TSV, the TSV penetrates through the substrate and the dielectric layer, and each silicon blind hole does not penetrate through the substrate.

At S404, a RDL interconnected with the at least one silicon blind hole and the TSV is formed on the second surface of the substrate, where the STI layer is formed on a first surface of the substrate, and the second surface of the substrate is a surface opposite to the first surface of the substrate in a thickness direction of the substrate.

As shown in FIG. 4B, the RDL 212 interconnected with the at least one silicon blind hole 206 and the TSV 205 is formed on the second surface of the substrate 201.

In the embodiment, all the silicon blind holes and TSVs are connected with the RDL on the second surface of the substrate, and heat is transmitted to a metal line in the RDL in the shortest distance, so as to realize the efficiency thermal gradient and improve the thermal transmission effect, and noises from the substrate can be shielded by the grounded RDL.

In actual application, the STI layer is formed by an STI technology. Specifically, a trench is formed by depositing, patterning and etching silicon using a silicon nitride mask, and the trench is filled with deposited oxide for isolation from silicon.

In some embodiments, the process of forming the TSV and the at least one silicon blind hole in S403 may be realized by S202 and S203 or S302 to S304.

Based on FIG. 4B, the embodiments of the disclosure further provide a thermal conduction structure, which may include a substrate 201, a STI layer 211, a metal layer 207, a TSV 205, at least one silicon blind hole 206 and a RDL 212.

The substrate 201 is provided. The STI layer 211 is located between the substrate 201 and the dielectric layer 220. The metal layer 207 is located on the dielectric layer 220.

The TSV 205 penetrates through the substrate 201, the STI layer 211 and the dielectric layer 202, and lands on the TSV 205 of the metal layer 207.

The at least one silicon blind hole 206 is located on at least one side of the TSV 205, and each silicon blind hole 206 does not penetrate through the substrate 201.

The RDL 212 is located on the second surface of the substrate 201 and interconnected with the at least one silicon blind hole 206 and the TSV 205, where the STI layer 211 is located on the first surface of the substrate 201, and the second surface of the substrate 201 is a surface opposite to the first surface of the substrate 201 in a thickness direction of the substrate 201.

In some embodiments, diameters of the TSV and the at least one silicon blind hole are 2 μm to 10 μm, the depth of the TSV is 40 μm to 100 μm, and the depth of the at least one silicon blind hole is 5 μm to 67 μm.

In actual application, due to the relatively small aperture, relatively large depth and relatively high aspect ratio of the TSV, electroplating voids will be formed when Cu plating is formed by a uniform electroplating process. Therefore, a “bottom-to-top” electroplating process in a related art may be adopted, and special electroplating accelerators and inhibitors may be used to accelerate the deposition rate inside the through hole and inhibit the deposition rate on the outer surface of the through hole. By adjusting the proportion of the accelerator and the inhibitor, the two may balance each other, so as to prevent the generation of electroplating voids.

In some embodiments, the distance on the substrate that is not penetrated by the at least one silicon blind hole is 3 μm to 65 μm.

Besides, the embodiments of the disclosure further provide a chip, which may at least include the above thermal conduction structure.

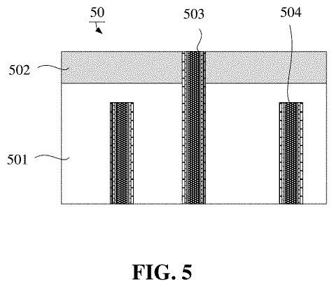

In some embodiments, as shown in FIG. 5, the chip 50 may at least include a thermal conduction structure, and the thermal conduction structure may include: a substrate 501; a dielectric layer 502 formed on the substrate 501; a TSV 503 penetrating through the substrate 501 and the dielectric layer 502; and at least one silicon blind hole 504 located on at least one side of the TSV 503, and each silicon blind hole 504 does not penetrate through the substrate 501.

In some embodiments, the thermal conduction structure may be shown with reference to FIG. 2F, FIG. 3E or FIG. 4B.

The method for forming a thermal conduction structure in the chip in the embodiment of the disclosure is similar to the method for forming a thermal conduction structure in the above embodiment. The technical features not disclosed in detail in the embodiment of the disclosure can be understood with reference to description of the above embodiment.

Moreover, the embodiments of the disclosure further provide a chip stacking structure, which may include at least two chips, a pad and a bonding pad.

Each of the at least two chips may include the above thermal conduction structure.

The pad is located on the first surface of each chip, where the pad is connected with a TSV in the thermal conduction structure.

The bonding pad is located on the second surface of the chip, where the bonding pad is connected with a metal layer connected with the TSV, and the second surface of the chip is a surface opposite to the first surface of the chip in the thickness of the chip.

The pad on the first surface of the first chip of the at least two chips is electrically connected with the bonding pad on the second surface of the second chip of the at least two chips.

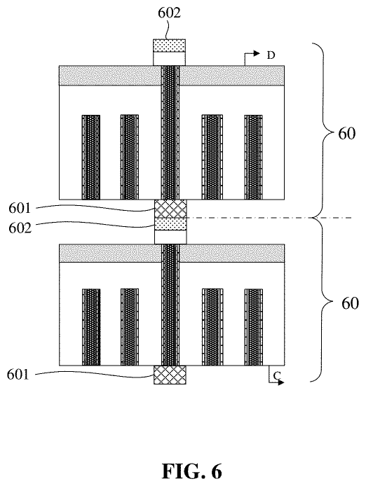

In some embodiments, there are two chips. As shown in FIG. 6, the chip stacking structure may include two chips 60, a pad 601 and a bonding pad 602. Each of the two chips 60 may include the above thermal conduction structure.

The pad 601 is located on the first surface (the surface C as shown in FIG. 6) of each chip 60, where the pad 601 is connected with the TSV in the thermal conduction structure.

The bonding pad 602 is located on the second surface (the surface D as shown in FIG. 6) of the chip 60, where the bonding pad 602 is connected with the metal layer connected with the TSV, and the second surface of the chip 60 is a surface opposite to the first surface of the chip 60 in a thickness of the chip 60.

The pad 601 on the first surface of the first chip of the two chips 60 is electrically connected with the bonding pad 602 on the second surface of the second chip of the two chips 60.

The thermal conduction structure may be shown with reference to FIG. 2E, FIG. 2F, FIG. 3E or FIG. 4B.

In some embodiments, there may be four, six, eight, or other numbers of the chips.

The method for forming a thermal conduction structure in the chip in the embodiment of the disclosure is similar to the method for forming a thermal conduction structure in the above embodiment. The technical features not disclosed in detail in the embodiment of the disclosure can be understood with reference to description of the above embodiment. The features disclosed in several methods or device embodiments provided by the disclosure may be combined arbitrarily without conflict to obtain new method embodiments or device embodiments.

The above is only the specific implementation mode of the disclosure and not intended to limit the scope of protection of the disclosure. Modifications or replacements are apparent to those skilled in the art within the technical scope disclosed by the disclosure, and these modifications or replacements shall fall within the scope of protection of the disclosure. Therefore, the scope of protection of the disclosure should be subject to the appended claims.

1. A method for forming a thermal conduction structure, the method comprising:
providing a substrate, at least a dielectric layer being formed on the substrate; and
forming a Through Silicon Via (TSV) and at least one silicon blind hole, wherein the at least one silicon blind hole is located on at least one side of the TSV, the TSV penetrates through the substrate and the dielectric layer, and each silicon blind hole does not penetrate through the substrate.

2. The method of claim 1, wherein the substrate further comprises a metal layer formed on the dielectric layer, and the TSV lands on the metal layer.

3. The method of claim 2, wherein the dielectric layer is formed on a first surface of the substrate; and
forming the TSV and the at least one silicon blind hole comprises:
etching the substrate and the dielectric layer from a second surface of the substrate to form the TSV penetrating through the substrate and the dielectric layer, wherein the second surface of the substrate is a surface opposite to the first surface of the substrate in a thickness direction of the substrate; and
etching the substrate from the second surface of the substrate to form the at least one silicon blind hole which does not penetrate through the substrate.

4. The method of claim 2, wherein the dielectric layer is formed on a first surface of the substrate; and forming the TSV and the at least one silicon blind hole comprises:
etching the substrate from a second surface of the substrate to form at least two blind holes which do not penetrate through the substrate, wherein the second surface of the substrate is a surface opposite to the first surface of the substrate in a thickness direction of the substrate;
continuously etching one of the at least two blind holes to form the TSV; and
forming the silicon blind hole in each remaining blind hole of the at least two blind holes.

5. The method of claim 4, wherein continuously etching one of the at least two blind holes to form the TSV comprises:
continuously etching the blind hole located in a middle of the substrate among the at least two blind holes to form the TSV.

6. The method of claim 4, wherein continuously etching one of the at least two blind holes to form the TSV comprises:
forming a barrier layer on each remaining blind hole;
etching the substrate and the dielectric layer in the blind hole corresponding to the TSV to form the TSV; and
removing the barrier layer.

7. The method of claim 6, wherein etching the substrate and the dielectric layer in the blind hole corresponding to the TSV to form the TSV comprises: etching the substrate and the dielectric layer in the blind hole to form a through hole; and sequentially forming an insulating layer, a barrier layer, a seed layer and a conductive layer in the through hole to obtain the TSV; and
forming the silicon blind hole in each remaining blind hole of the at least two blind holes comprises: sequentially forming the insulating layer, the barrier layer, the seed layer and the conductive layer in each remaining blind hole to obtain the silicon blind hole.

8. The method of claim 1, wherein an insulating layer, a barrier layer, a seed layer and a conductive layer sequentially formed are included in the TSV and each silicon blind hole, wherein a thickness of the insulating layer is 2000 Å to 5000 Å.

9. The method of claim 8, wherein at least one of:
the insulating layers of the TSV and the silicon blind hole that are adjacent to each other are spaced apart by a distance of 1.5 μm, or
the insulating layers of two adjacent silicon blind holes are spaced apart by a distance of 1.5 μm.

10. The method of claim 8, wherein a thickness of the insulating layer in the TSV is greater than a thickness of the insulating layer in the silicon blind hole.

11. The method of claim 1, wherein the dielectric layer is formed on a first surface of the substrate, and the method further comprises:
forming a Redistribution Layer (RDL) interconnected with the at least one silicon blind hole and the TSV on a second surface of the substrate, wherein the second surface of the substrate is a surface opposite to the first surface of the substrate in a thickness direction of the substrate.

12. The method of claim 1, further comprising:
sequentially forming a Shallow Trench Isolation (STI) layer, the dielectric layer and a metal layer on the substrate.

13. The method of claim 1, wherein:
a thickness of the substrate is 40 μm to 70 μm;
diameters of the TSV and the at least one silicon blind hole are 2 μm to 10 μm; and
a depth of the TSV is 40 μm to 100 μm, and a depth of the at least one silicon blind hole is 5 μm to 67 μm.

14. The method of claim 1, wherein a portion of the substrate that is not penetrated by the at least one silicon blind hole has a thickness of 3 μm to 65 μm.

15. A thermal conduction structure, comprising:
a substrate;
a dielectric layer formed on the substrate;
a Through Silicon Via (TSV) penetrating through the substrate and the dielectric layer; and
at least one silicon blind hole located on at least one side of the TSV, wherein each silicon blind hole does not penetrate through the substrate.

16. The thermal conduction structure of claim 15, further comprising a metal layer formed on the dielectric layer, wherein the TSV lands on the metal layer.

17. The thermal conduction structure of claim 16, wherein the TSV is located among the at least one silicon blind hole.

18. The thermal conduction structure of claim 15, wherein an insulating layer, a barrier layer, a seed layer and a conductive layer are included in the TSV and each silicon blind hole; and
a thickness of the insulating layer is 2000 Å to 5000 Å.

19. A chip, comprising at least the thermal conduction structure of claim 15.

20. A chip stacking structure, comprising: at least two chips,
each of the at least two chips comprising the thermal conduction structure of claim 15;
a pad located on a first surface of each chip, wherein the pad is connected with a Through Silicon Via (TSV) in the thermal conduction structure; and
a bonding pad located on a second surface of each chip, wherein the bonding pad is connected with a metal layer connected with the TSV, and the second surface of the chip is a surface opposite to the first surface of the chip in a thickness of the chip,
wherein the pad on the first surface of a first chip of the at least two chips is electrically connected with the bonding pad on the second surface of a second chip of the at least two chips.
